(19) United States
(12) Patent Application Publication
(10) Pub. No.: US 2023/0420463 A1
(43) Pub. Date: Dec. 28, 2023

(54) CONNECTION STRUCTURE AND ELECTRONIC DEVICE INCLUDING THE SAME

(71) Applicant: Innolux Corporation, Miaoli County (TW)

(72) Inventors: Ming-Jou Tai, Miaoli County (TW); Chia-Hao Tsai, Miaoli County (TW); Ming-Chih Tsai, Miaoli County (TW)

(73) Assignee: Innolux Corporation, Miaoli County (TW)

(21) Appl. No.: 18/464,248

(22) Filed: Sep. 10, 2023

Related U.S. Application Data
(63) Continuation of application No. 17/098,465, filed on Nov. 16, 2020.
(60) Provisional application No. 62/944,376, filed on Dec. 6, 2019.

(30) Foreign Application Priority Data
Oct. 12, 2020 (CN) 202011083650.9

(51) Int. Cl. H01L 27/12; G02F 1/1362; H10K 59/123

(52) U.S. Cl. CPC H01L 27/1244; H01L 27/1248; G02F 1/136227; H10K 59/123

(57) ABSTRACT

A connection structure and a display device including the connection structure are provided. The connection structure includes a first wire, a second wire, and an insulating layer. The insulating layer is disposed between the first wire and the second wire, and the insulating layer has a through hole surrounded by a side wall. A connection portion of the second wire is electrically connected to the first wire through the through hole. The connection portion of the second wire ends on the side wall of the through hole.

### CROSS-REFERENCE TO RELATED APPLICATION

This application is a continuation application of and claims the priority benefit of U.S. application Ser. No. 17/098,465, filed on Nov. 16, 2020, which claims the priority benefit of U.S. provisional application Ser. No. 62/944,376, filed on Dec. 6, 2019, and China application serial no. 202011083650.9, filed on Oct. 12, 2020. The entirety of each of the above-mentioned patent applications is hereby incorporated by reference herein and made a part of this specification.

### BACKGROUND

### Technical Field

The disclosure relates to an electronic device, and particularly relates to a connection structure and an electronic device including the connection structure.

### Description of Related Art

Along with continues increase of applications of electronic devices, display technology is also developed rapidly. Along with different application conditions, requirements on display quality of the electronic devices are getting higher and higher, and the electronic devices accordingly face different problems. Therefore, research and development of electronic devices must be continuously updated and adjusted.

### SUMMARY

The disclosure is directed to a connection structure and an electronic device including the connection structure, which has better display quality.

An embodiment of the disclosure provides a connection structure including a first wire, a second wire, and an insulating layer. The insulating layer is disposed between the first wire and the second wire, and the insulating layer has a through hole surrounded by a side wall. A connection portion of the second wire is electrically connected to the first wire through the through hole. The connection portion of the second wire ends on the side wall of the through hole.

An embodiment of the disclosure provides an electronic device includes the aforementioned connection structure.

### BRIEF DESCRIPTION OF THE DRAWINGS

FIG. 1 is a partially enlarged schematic top view of a display device according to an embodiment of the disclosure.

FIG. 2 is a schematic cross-sectional view of FIG. 1 viewing along a section line A-A′.

FIG. 3 is a schematic cross-sectional view of a display device according to another embodiment of the disclosure.

FIG. 4 is a partially enlarged schematic top view of a display device according to another embodiment of the disclosure.

FIG. 5A is a partially enlarged schematic diagram of a second wire according to another embodiment of the disclosure.

FIG. 5B is a partially enlarged schematic diagram of a second wire according to still another embodiment of the disclosure.

FIG. 6 is a schematic cross-sectional view of FIG. 4 viewing along a section line B-B′.

### DESCRIPTION OF THE EMBODIMENTS

In the disclosure, when one structure (or layer, component, substrate) is described to be located on another structure (or layer, component, substrate), it means that the two structures are adjacent and directly connected (or contacted), or means that the two structures are adjacent but not directly connected (or contacted). Indirect connection means that there is at least one intermediate structure (or intermediate layer, intermediate component, intermediate substrate, intermediate space) between the two structures, and a lower surface of one structure is adjacent or directly connected to an upper surface of the intermediate structure, and an upper surface of the other structure is adjacent or directly connected (or contacted) to a lower surface of the intermediate structure, and the intermediate structure may be composed of a single layer or multi-layer solid structure or non-solid structure, which is not limited by the disclosure. In the disclosure, when a certain structure is disposed “on” another structure, it may mean that the certain structure is “directly” on the another structure, or that the certain structure is “indirectly” on the another structure, i.e., at least one structure is sandwiched between the certain structure and the another structure.

Electrical connections or couplings described in the disclosure may all refer to direct connections or indirect connections. In the case of the direct connection, terminals of components on two circuits are directly connected or connected to each other by a conductive wire segment. In the case of the indirect connection, there are other components between the terminals of the components on the two circuits, such as a combination of one of a switch, a diode, a capacitor, an inductor, or other non-conductive wire segment and at least one conductive segment or a resistor, or a combination of at least two of the above components and at least one conductive segment or a resistor.

The disclosure may be understood by referring to the following detailed description in collaboration with the accompanying drawings. It should be noted that, in order to make the readers easy to understand and for conciseness of the drawings, the multiple drawings in the disclosure only depict a part of the electronic device, and the specific components in the drawings are not drawn according to actual scales. In addition, the number and size of each component in the figures are only for illustration, and are not used to limit the scope of the disclosure.

In the disclosure, thicknesses, lengths, and widths may be measured by using an optical microscope, or the thickness may be obtained by measuring a cross-sectional image in an electron microscope, but the disclosure is not limited thereto. Moreover, there may be a certain error in any two values or directions used for comparison. If the first value is equal to the second value, it implies that there may be an error of about 10% between the first value and the second value; if the first direction is perpendicular to the second direction, an angle between the first direction and the second direction may be between 80 degrees and 100 degrees; and if the first direction is parallel to the second direction, the angle between the first direction and the second direction may be between degrees and 10 degrees. The terms “about”, “approximately”, and “mostly” generally indicate to be within 20%, or within 10%, or within 5% of a given value or range. A given quantity is an approximate quantity, i.e., the meanings of “about”, “approximately”, and “mostly” may still be implied in case of no specific instructions.

Certain terms are used throughout the specification of the disclosure and the appended claims to refer to specific components. Those skilled in the art should understand that electronic device manufacturers may probably use different names to refer to the same components. This specification is not intended to distinguish between components that have the same function but different names. In the following specification and claims, the terms “containing”, “including”, etc., are open terms, so that they should be interpreted as meaning of “including but not limited to . . . ”. Therefore, when the terms “including”, “containing”, and/or “having” are used in the description of the disclosure, they specify existence of corresponding features, regions, steps, operations, and/or components, but do not exclude existence of one or more corresponding features, regions, steps, operations, and/or components.

Directional terminology mentioned in the specification, such as “top”, “bottom”, “front”, “back”, “left”, “right”, etc., is used with reference to the orientation of the figures being described. Therefore, the used directional terminology is only illustrative, and is not intended to be limiting of the disclosure. In the figures, the drawings illustrate general characteristics of methods, structures, and/or materials used in specific embodiments. However, these drawings should not be construed as defining or limiting of a scope or nature covered by these embodiments. For example, for clarity's sake, a relative size, a thickness and a location of each film layer, area and/or structure may be reduced or enlarged.

Although the terms first, second, third . . . can be used to describe various components, the components are not limited to these terms. These terms are only used to distinguish a single component from other components in the specification. The same terms may not be used in the claims, and the components may be described as first, second, third components . . . according to an order declared in the claims. Therefore, in the following description, the first component may be the second component in the claims.

An electronic device of the disclosure may include a display device, an antenna device, a sensing device, a splicing device or a transparent display device, but the disclosure is not limited thereto. The electronic device may be a rollable, stretchable, bendable or flexible electronic device. The electronic device may include, for example, liquid crystal, light-emitting diodes (LEDs), quantum dots (QDs), fluorescence, phosphor, or other suitable materials and their materials may be arbitrarily arranged and combined or other suitable display media, or combinations thereof; the LEDs may include, for example, organic light-emitting diodes (OLEDs), mini LEDs, micro LEDs or quantum dot (QD) LEDs (for example, QLEDs, or QDLEDs), but the disclosure is not limited thereto. The antenna device may be, for example, a liquid crystal antenna, but the disclosure is not limited thereto. The splicing device may be, for example, a display splicing device or an antenna splicing device, but the disclosure is not limited thereto. It should be noted that the electronic device may be any arrangement and combination of the foregoing, but the disclosure is not limited thereto. In addition, an appearance of the electronic device may be a rectangle, a circle, a polygon, a shape with curved edges, or other suitable shapes. The electronic device may have peripheral systems such as a driving system, a control system, a light source system, a rack system, etc., to support the display device, the antenna device or the splicing device. Hereinafter, a semiconductor device is used to illustrate the content of the disclosure, but the disclosure is not limited thereto.

In the disclosure, the various embodiments described below may be mixed and matched without departing from the spirit and scope of the disclosure. For example, some features of one embodiment may be combined with some features of another embodiment to form another embodiment.

Reference will now be made in detail to the exemplary embodiments of the disclosure, and examples of the exemplary embodiments are illustrated in the accompanying drawings. Whenever possible, the same component symbols are used in the drawings and descriptions to indicate the same or similar parts.

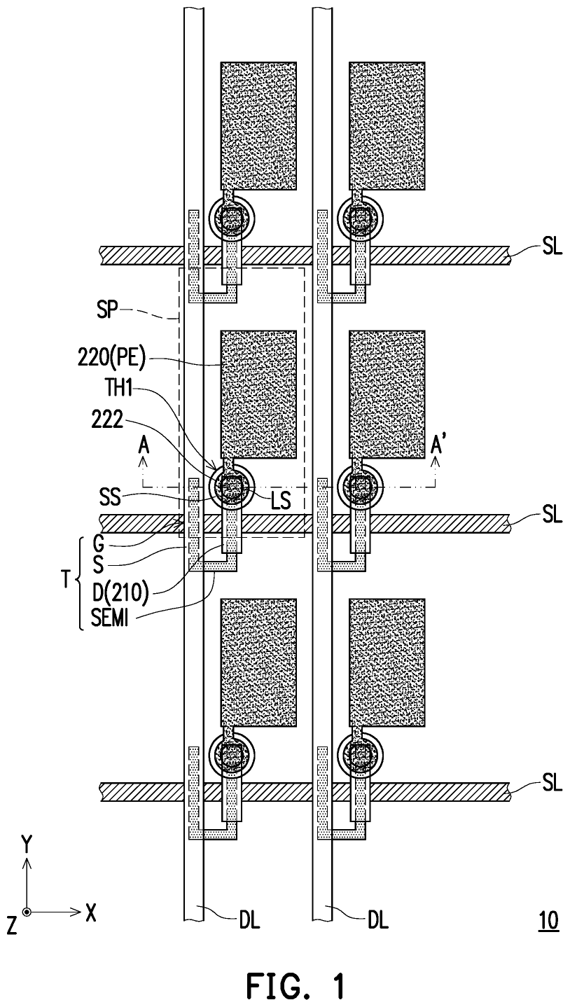

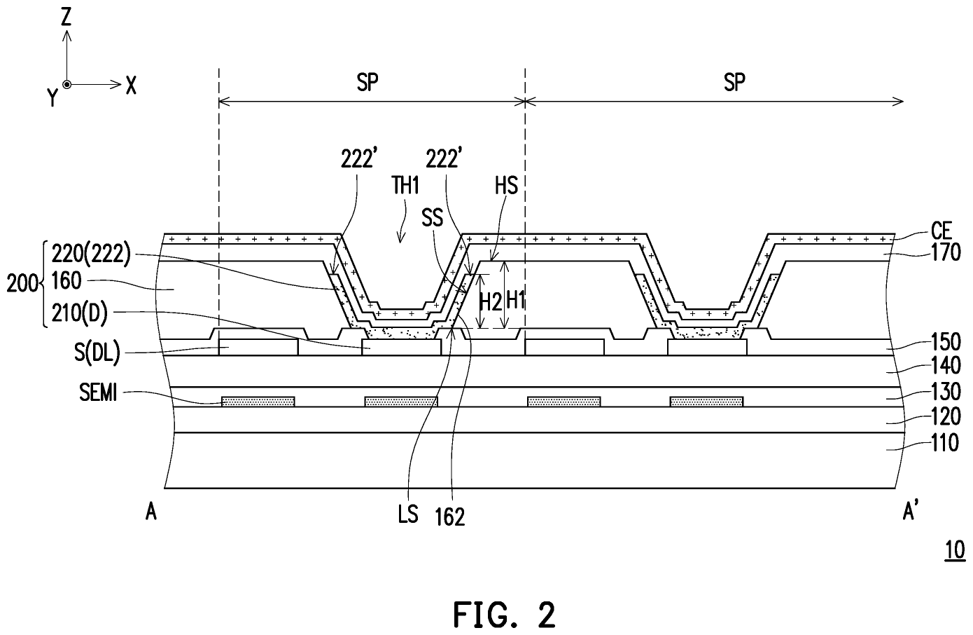

FIG. 1 is a partially enlarged schematic top view of a display device serving as an electronic device according to an embodiment of the disclosure. FIG. 2 is a schematic cross-sectional view of FIG. 1 viewing along a section line A-A′. For the clarity of the drawings and the convenience of description, several elements are omitted in FIG. 1 and FIG. 2. Referring to FIG. 1 and FIG. 2, FIG. 1 and FIG. 2 show a part of a display device 10, including first signal lines SL, second signal lines DL, thin film transistors T, a plurality of sub-pixels SP and a connection structure 200. In the embodiment, through the arrangement of the connection structure 200, the display device 10 may have better display quality.

Referring to FIG. 1 and FIG. 2, the display device 10 includes a substrate 110, a first signal line SL disposed on the substrate 110, a second signal line DL disposed on the substrate 110, a thin film transistor T, a pixel electrode PE, and a common electrode CE, but the disclosure is not limited thereto. In addition, the display device 10 further includes a plurality of insulating layers 120, 130, 140, 150, 160, 170, etc., that are sequentially stacked, but the disclosure is not limited thereto. In the disclosure, one insulating layer may represent a single-layer structure or a multi-layer structure. For example, the insulating layer 120 may be a single-layer structure or a multi-layer structure, which is not limited by the disclosure. In some embodiments, a shielding layer (not shown) may be disposed on the substrate 110, and the insulating layer 120 may be disposed on the substrate 110 to cover the shielding layer. A material of the substrate 110 includes glass, quartz, sapphire, ceramics, polycarbonate (PC), polyimide (PI), polyethylene terephthalate (PET), rubber, glass fiber, other suitable substrate materials, or a combination of thereof, but the disclosure is not limited thereto. The shielding layer includes a light shielding material, such as a metal material or a photoresist material, but the disclosure is not limited thereto.

The thin film transistor T is disposed on the insulating layer 120. The thin film transistor T includes a gate G, a semiconductor layer SEMI, a source S and a drain D. In some embodiments, in a normal direction (a Z axis direction) of the substrate 110, the shielding layer may be overlapped with at least a part of the semiconductor layer SEMI. The shielding layer may be used to shield light irradiated from a bottom surface of the substrate 110 to the semiconductor layer SEMI. A material of the semiconductor layer SEMI includes monocrystalline silicon, polycrystalline silicon, amorphous silicon, metal oxide materials, organic semiconductor materials, other suitable materials, or a combination of thereof. In some embodiments, the insulating layer 130 is disposed on the semiconductor layer SEMI. In some embodiments, the first signal line SL is disposed on the insulating layer 130 (for example, a gate insulating layer). In the normal direction (the Z axis direction) of the substrate 110, a part of the first signal line SL (for example, a scan line) is overlapped with the semiconductor layer SEMI to serve as the gate G, i.e., the gate G is electrically connected to the first signal line SL. The part of the semiconductor layer SEMI overlapped with the gate G may be defined as a channel region, and the part of the semiconductor layer SEMI on two opposite sides of the channel region may be respectively used as a source region and a drain region. The insulating layer 140 is disposed on the first signal line SL, and the second signal line DL is disposed on the insulating layer 140. In some embodiments, the insulating layer 130 and/or the insulating layer 140 may form a via hole (not shown), and the part of the second signal line DL (for example, a data line) that is electrically connected to the semiconductor layer SEMI (for example, the source region) through the via hole may be defined as the source S, but the disclosure is not limited thereto. In addition, a first wire 210 (for example, the drain D) may be disposed on the insulating layer 140 and electrically connected to the semiconductor layer SEMI (for example, the drain region) through the via hole. In this way, the first wire 210 may be electrically connected to the second signal line DL through the semiconductor layer SEMI. When the thin film transistor T is turned on, a signal on the first wire 210 may be transmitted to the second signal line DL through the semiconductor layer SEMI. The insulating layer 150 is disposed on the source S and/or the drain D. In the embodiment, the first signal line SL, the second signal line DL, the source S and the drain D may be made of molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), other suitable metals, or alloys or combinations of the above materials, but the disclosure is not limited thereto. In some embodiments, the thin film transistor T may include a top gate transistor, a bottom gate transistor, a dual gate transistor, and a double gate transistor as needed, but the disclosure is not limited thereto.

In the embodiment, the first signal line SL extends along an X axis direction, and the second signal line DL extends along a Y axis direction. The first signal line SL and the second signal line DL are arranged in intersection, and the first signal line SL and the second signal line DL are overlapped in the Z axis direction. As shown in FIG. 1 of the embodiment, the X axis is perpendicular to the Y axis, and the Z axis is perpendicular to the X axis or the Y axis.

In some embodiments, the insulating layer 160 is disposed on the second signal line DL and/or the drain D. In the normal direction (the Z axis direction) of the substrate 110, the insulating layer 150 may have a via hole overlapped with the first wire 210 (for example, the drain D). The insulating layer 160 has a through hole TH1 overlapped with the via hole of the insulating layer 150 to expose the first wire 210. In some embodiments (not shown), the insulating layer 160 may be directly disposed on the second signal line DL and/or the first wire 210, i.e., the insulating layer 150 is not provided, and the through hole TH1 is provided to expose the first wire 210. A second wire 220 (for example, the pixel electrode PE) is disposed on the insulating layer 160 and extends into the through hole TH1 to be electrically connected to the first wire 210. The insulating layer 170 is disposed on the insulating layer 160 and may be filled in the through hole TH1. The common electrode CE is disposed on the insulating layer 170. In some embodiments, a material of the insulating layer 120, the insulating layer 130, the insulating layer 140, the insulating layer 150, and the insulating layer 170 may include an organic insulating material or an inorganic insulating material, but the disclosure is not limited thereto. In some embodiments, the insulating layer 120, the insulating layer 130, the insulating layer 140, the insulating layer 150, and the insulating layer 170 may, for example, respectively include a single-layer structure or a multi-layer structure, but the disclosure is not limited thereto. In some embodiments, the second wire 220 may be the pixel electrode PE, and a material thereof may include a transparent conductive material, such as indium tin oxide, indium zinc oxide, indium oxide, tin oxide, other suitable materials, or a combination thereof, or may include an opaque material, such as aluminum, molybdenum, copper, titanium, other suitable materials, or a combination thereof, which is not limited by the disclosure. In some embodiments, a material of the common electrode CE includes a transparent conductive material, such as indium tin oxide, indium zinc oxide, indium oxide, tin oxide, other suitable materials or a combination thereof, or includes an opaque material, such as aluminum, molybdenum, copper, titanium, other suitable materials or a combination thereof, but the disclosure is not limited thereto. In some embodiments, the materials of the common electrode CE and the second wire 220 may be the same or different.

Referring to FIG. 1, FIG. 1 illustrates a partial sub-pixel array of the display device 10. The sub-pixel SP includes, for example, the second wire 220 (for example, the pixel electrode PE) and the thin film transistor T. The sub-pixel SP may be defined by two adjacent first signal lines SL and two adjacent second signal lines DL. Taking FIG. 1 as an example, the sub-pixels SP may be arranged in three rows along the X axis direction, and arranged in two columns along the Y axis direction. It should be noted that FIG. 1 schematically illustrates 6 sub-pixels SP, but the actual number and arrangement pattern thereof may be changed according to actual needs of the user, which are not limited to that shown in FIG. 1.

In some embodiments, the pixel electrode PE is electrically connected to the thin film transistor T. Referring to FIG. 1 and FIG. 2 at the same time, in detail, the connection structure 200 may include the first wire 210, the second wire 220 and the insulating layer 160. In the embodiment, the first wire 210 may be the drain D, and the second wire 220 may be the pixel electrode PE, but the disclosure is not limited thereto. At least a part of the insulating layer 160 is sandwiched between the first wire 210 and the second wire 220. The insulating layer 160 has the through hole TH1 surrounded by a side wall 162. The second wire 220 has a connection portion 222 overlapped with the through hole TH1 in the Z axis direction. The connection portion 222 is electrically connected to the first wire 210 (for example, the drain D) through the through hole TH1. In some embodiments, the insulating layer 160 may include an organic material. For example, the organic material may include polyethylene terephthalate (PET), polyethylene (PE), polyethersulfone (PES), polycarbonate (PC), polymethylmethacrylate (PMMA), polyimide (PI), photo sensitive polyimide (PSPI) or a combination thereof, the insulating layer 160 may also include an inorganic material. For example, the inorganic material may include silicon oxide (SiOx), silicon nitride (SiNx), or a combination thereof, but the disclosure is not limited thereto.

In some embodiments, the side wall 162 has a high level surface HS and a low level surface LS. The high level surface HS may be, for example, the top of the side wall 162, and the low level surface LS may be, for example, the bottom of the side wall 162. The side wall 162 surrounding the through hole TH1 has an inclined surface SS. The inclined surface SS is located between the high level surface HS and the low level surface LS and may be connected to the high level surface HS and the low level surface LS. A height H1 of the side wall 162 of the through hole TH1 may be defined by a distance between the low level surface LS and the high level surface HS on the Z axis direction. In some embodiments, a height difference between the high level surface HS and the low level surface LS (i.e. the height H1) may be between 1 μm to 6 μm (1 μm≤height difference≤6 μm), 2 μm to 6 μm (2 μm≤height difference≤6 μm), 2 μm to 3 μm (2 μm≤height difference≤3 μm), 3 μm to 5 μm (3 μm≤height difference≤5 μm), but the disclosure is not limited thereto. In some embodiments (not shown), the inclined surface SS may also have an arc-shaped curved surface in a cross-section.

In some embodiments, in a plan view (in the Z axis direction), a pattern of the through hole TH1 or the side wall 162 surrounding the through hole TH1 may be a circle, but the disclosure is not limited thereto. In other embodiments (not shown), the pattern of the through hole TH1 or the sidewall 162 of the through hole TH1 may also be a rectangle, a polygon, an ellipse, or an irregular shape, which is not limited by the disclosure.

It should be noted that in a display device with a high resolution requirement, the size of the sub-pixel SP becomes smaller. Therefore, the portion of the pixel electrode PE connected to the drain D is arranged on a bottom surface of the through hole TH1 as much as possible to reduce the contact of the adjacent pixel electrodes PE to cause a short circuit. However, in a photolithography process, since a light path of the connection portion 222 of the pixel electrode PE provided on the bottom surface of the through hole TH1 is longer than the pixel electrode PE provided on a top surface of the insulating layer 160, when the pixel electrode PE is patterned, exposure of the pixel electrode PE on the top surface of the insulating layer 160 increases, which causes over-exposure, and results in reduction in the size of the pixel electrode PE, and may cause abnormal electrical connection of the display device or affect storage capacitance due to the size reduction of the pixel electrode PE, thus reducing the display quality.

It should be noted that the display device 10 of the embodiment of the disclosure includes the connection structure 200, and the connection portion 222 of the second wire 220 of the connection structure 200 ends on the side wall 162 of the through hole TH1. Specifically, the second wire 220 (for example, the pixel electrode PE) may extend from the insulating layer 160 into the through hole TH1. The connection portion 222 of the second wire 220 may be defined as a portion of the second wire 220 in the through hole TH1 or overlapped with the through hole TH1. To be more specific, the connection portion 222 ends on the inclined surface SS of the side wall 162 of the through hole TH1. In this way, the connection portion 222 does not exceed a contour of the through hole TH1, so that the risk of contact between the adjacent second wires 220 (for example, the pixel electrodes PE) may be reduced, or the chance of electrical abnormality may be reduced.

In addition, an outer edge 222′ of the connection portion 222 is set at a position not less than 10% of the height H1 of the side wall 162, and the outer edge 222′ of the connection portion 222 is set at a position not greater than 90% of the height H1 of the side wall 162. In other words, a height H2 of the connection portion 222 on the side wall 162 may be greater than or equal to 10% of the height H1, or less than or equal to 90% of the height H1. In some other embodiments, the outer edge 222′ of the connection portion 222 is set at a position not less than 20% of the height H1 of the side wall 162, and the outer edge 222′ of the connection portion 222 is set at a position not greater than 80% of the height H1 of the side wall 162. In other words, the height H2 of the connection portion 222 on the side wall 162 may be greater than or equal to 20% of the height H1, or less than or equal to 80% of the height H1, but the disclosure is not limited thereto. In other words, the outer edge 222′ of the connection portion 222 stops on the inclined surface SS of the side wall 162. Since the connection portion 222 is disposed on the inclined surface SS, and its outer edge 222′ is located within the contour of the through hole TH1, in the photolithography process, the connection portion 222 may be subjected to a better amount of exposure, and the second wire 220 (for example, the pixel electrode PE) on the top surface of the insulating layer 160 is not easy to be overexposed. Under the above configuration, the size of the pixel electrode PE may be maintained to an appropriate size. In this way, the capacitance between the pixel electrode PE and the common electrode CE is less affected. The display device 10 may have better electrical quality or better display quality.

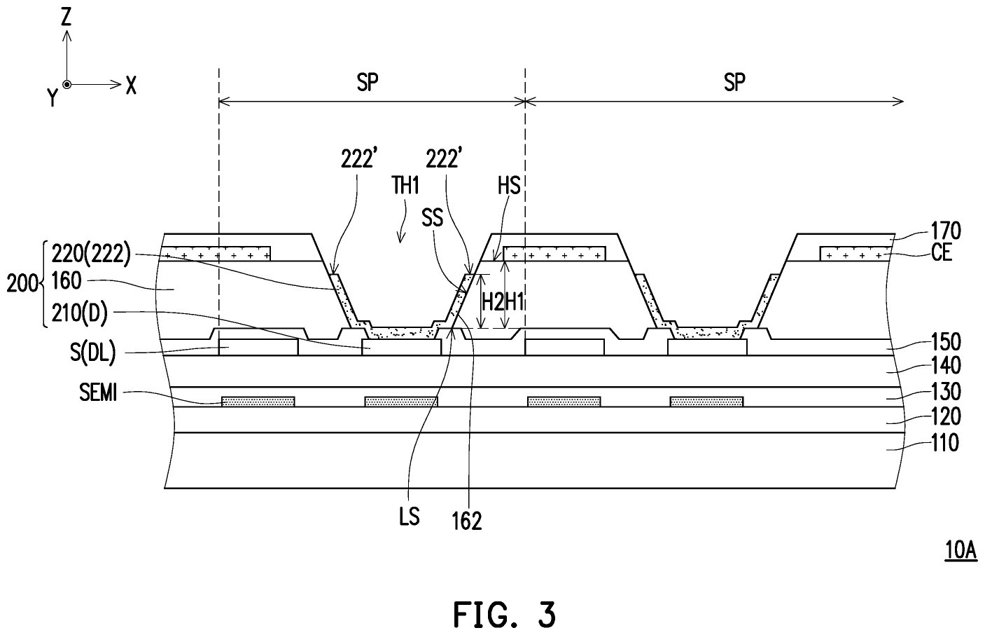

In the embodiment, the sub-pixel SP of the display device 10 is, for example, a top com electrode design, but the disclosure is not limited thereto. In some embodiments, FIG. 3 is a schematic cross-sectional view of a display device according to another embodiment of the disclosure. For clarity of the drawings and the convenience of description, several elements are omitted in FIG. 3. The display device 10A of the embodiment is substantially similar to the display device 10 of FIG. 2, so that the same and similar components in the two embodiments are not repeated here. A main difference between the display device 10A of the embodiment and the display device 10 is that the display device 10A is, for example, a top pixel electrode design. For example, the common electrode CE is disposed on the insulating layer 160. The common electrode CE may be arranged by surrounding the through hole TH1 without overlapping the through hole TH1 in the Z axis direction. The insulating layer 170 is disposed on the common electrode CE and covers the insulating layer 160. The insulating layer 170 may have a via hole overlapped with the through hole TH1 of the insulating layer 160. The via hole of the insulating layer 170, the through hole TH1 of the insulating layer 160, and the via hole of the insulating layer 150 may expose the first wire 210 (for example, the drain D). The connection portion 222 of the second wire 220 (for example, the pixel electrode PE) is disposed on the side wall 162 of the through hole TH1, and is electrically connected to the first wire 210 through the through hole TH1. In this way, the connection structure 200 or the display device 10A may achieve better technical effects similar to that of the aforementioned embodiment.

In brief, in the display device 10 including the connection structure 200 according to an embodiment of the disclosure, since the connection portion 222 of the second wire 220 of the connection structure 200 is disposed on the inclined surface SS of the side wall 162 of the through hole TH1 of the insulating layer 160, the second wires 220 of the adjacent sub-pixels SP are not easy to contact with each other, or the chance of electrical abnormality may be reduced. In addition, during the photolithography process, the connection portion 222 may be subjected to a better amount of exposure, and the second wire 220 (for example, the pixel electrode PE) on the top surface of the insulating layer 160 is not easy to be overexposed. Under the above configuration, the size of the pixel electrode PE may be maintained to an appropriate size. In this way, the capacitance between the pixel electrode PE and the common electrode CE is less affected. The display device 10A may have better electrical quality or better display quality.

Other embodiments are provided below for description. It must be noted that reference numbers of the components and a part of contents of the aforementioned embodiments are also used in the following embodiments, where the same reference numbers denote the same or like components, and descriptions of the same technical contents are omitted. The aforementioned embodiments may be referred for descriptions of the omitted parts, and detailed descriptions thereof are not repeated in the following embodiments.

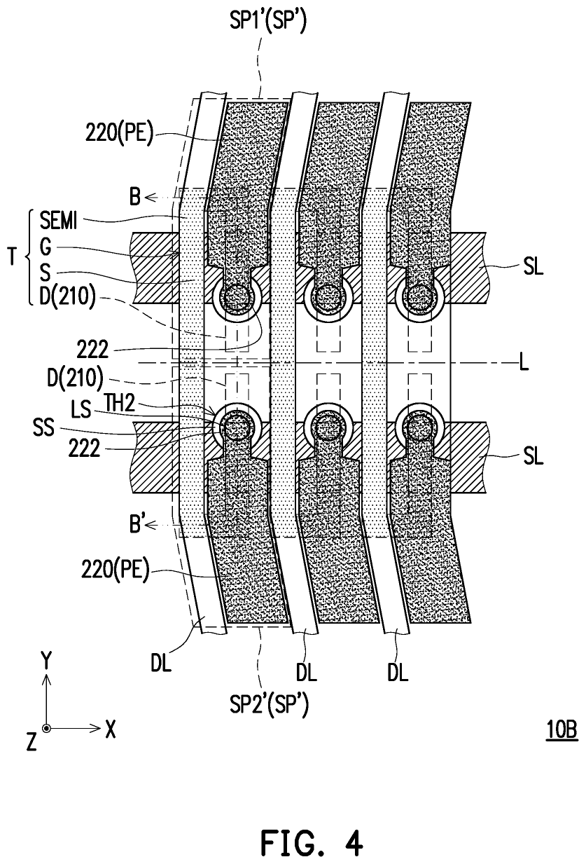

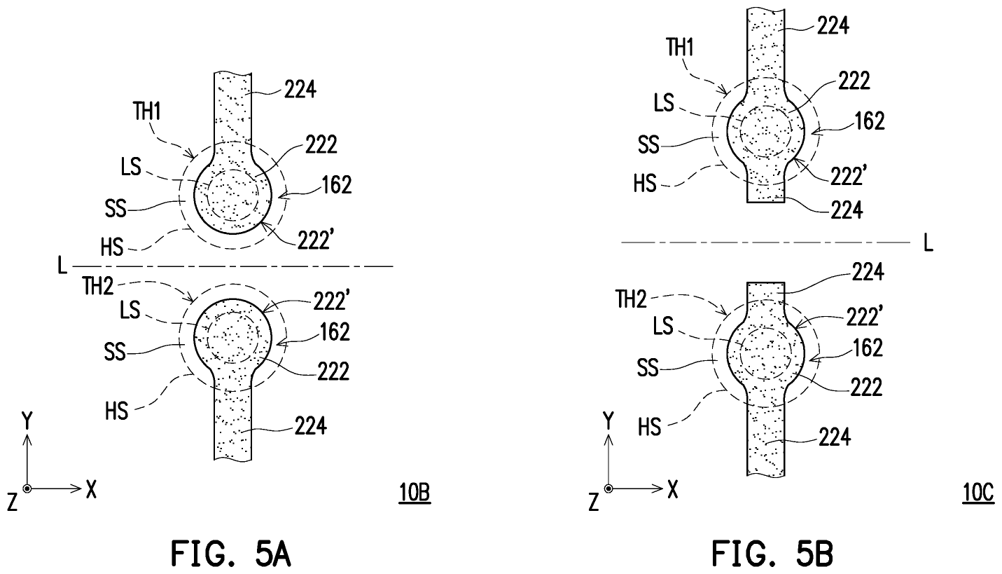

FIG. 4 is a partially enlarged schematic top view of a display device according to another embodiment of the disclosure. FIG. 5A is a partially enlarged schematic diagram of a second wire according to another embodiment of the disclosure. For the clarity of the drawings and the convenience of description, several elements are omitted in FIG. 4 and FIG. 5A. The display device 10B of the embodiment is substantially similar to the display device 10 of FIG. 1, so the same and similar components in the two embodiments are not repeated here. A main difference between the display device 10B of the embodiment and the display device 10 is that the connection portions 222 of the sub-pixels SF of the display device 10B are, for example, arranged adjacently in pairs. In detail, two adjacent first signal lines SL are disposed on the substrate 110 on upper and lower sides of an auxiliary line L, and the auxiliary line L and the first signal lines SL extend substantially along the X axis direction. In other words, the two first signal lines SL are disposed on both sides of the auxiliary line L in a mirror manner. At least three second signal lines DL extend along the Y axis direction, and the second signal lines DL are intersected with the first signal lines SL. Two adjacent second signal lines DL may define sub-pixels SF. A sub-pixel SP1′ and a sub-pixel SP2′ are respectively located on both sides of the auxiliary line L and arranged in the mirror manner. For example, the connection portion 222 of the second wire 220 (for example, the pixel electrode PE) of the sub-pixel SP1′ is disposed adjacent to one side of the auxiliary line L, and the connection portion 222 of the second wire 220 (for example, the pixel electrode PE) of the sub-pixel SP2′ is disposed adjacent to the other side of the auxiliary line L. According to another aspect, the sub-pixel SP1′ and the sub-pixel SP2′ arranged in pairs adopt a back to back design. In this way, a part of the through holes may be shared between the sub-pixels SF, so that an aperture ratio of the display device 10B may be increased. It should be noted that FIG. 4 schematically illustrates 6 sub-pixels SF (including the sub-pixel SP1′ and the sub-pixel SP2′), but the actual number and arrangement pattern may be changed according to the actual needs of the user, which are not limited to that shown in FIG. 4.

Referring to FIG. 4 and FIG. 5A, FIG. 5A is a partially enlarged schematic view of the through hole TH1 and the through hole TH2. The insulating layer 160 of the connection structure 200 has the through hole TH1 and the through hole TH2. The through hole TH1 or the through hole TH2 respectively expose the first wire 210 (for example, the drain D). The second wire 220 further includes a main portion 224, where the main portion 224 is, for example, an electrode portion where the pixel electrode PE is overlapped with the common electrode CE, and may also include a neck portion connected between the above mentioned electrode portion and the connection portion 222, but the disclosure is not limited thereto, which may be defined according to the actual needs of the user. As shown in FIG. 5A, the through hole TH1 (or the through hole TH2) is surrounded by the side wall 162. Viewing from the Z axis direction, the outermost edge of the side wall 162 of the through hole TH1 (or through hole TH2) is the top of the through hole TH1 (or through hole TH2), which is also the high level surface HS. The innermost edge of the side wall 162 of the through hole TH1 (or through hole TH2) is the bottom of the through hole TH1 (or through hole TH2), which is also the low level surface LS. The side wall 162 between the high level surface HS and the low level surface LS may have the inclined surface SS.

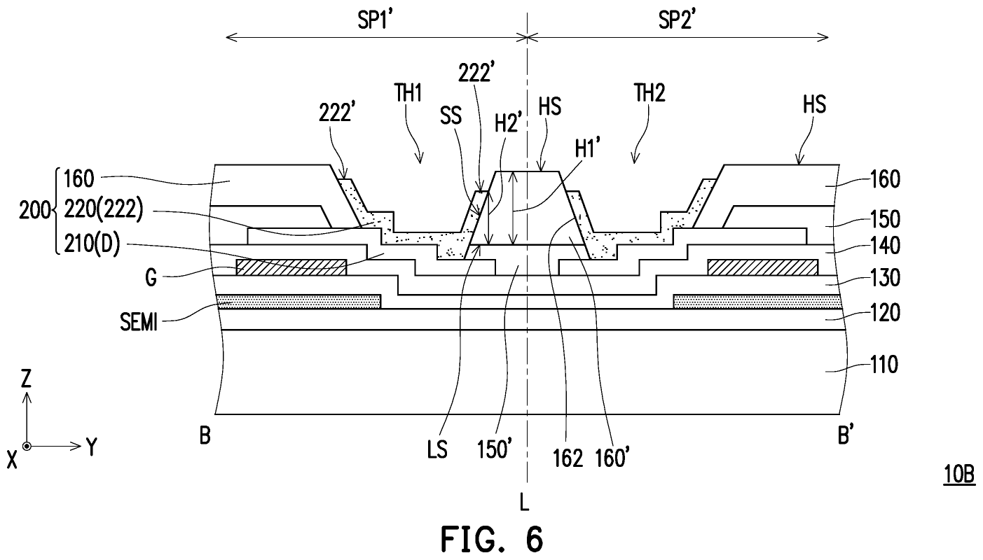

In some embodiments, the main portion 224 may be defined as a portion of the second wire 220 that is disposed on the top surface of the insulating layer 160 and substantially not overlapped with the through hole TH1 (or through hole TH2). As shown in FIG. 5A, the main body 224 is disposed on the insulating layer 160 or the high level surface HS, and the main body 224 may extend from the insulating layer 160 or the high level surface HS of the through hole TH1 (or through hole TH2) to the outer edge of the through hole TH1 (or through hole TH2), so as to be connected to the connection portion 222 on the side wall 162 surrounding the through hole TH1 (or through hole TH2). The connection portion 222 is defined as being disposed on the inclined surface SS of the side wall 162 surrounding the through hole TH1 (or through hole TH2), and is electrically connected to the first wire 210 (shown in FIG. 4 and FIG. 6) at the low level surface LS.

It should be noted that, according to the top views shown in FIG. 4 and FIG. 5A, since the connection portion 222 stops or ends on the inclined surface SS of the side wall 162 of the through hole TH1, the connection portions 222 of the adjacent second wires 220 are not easy to contact with each other, or the chance of electrical abnormality may be reduced. In addition, the connection structure 200 or the display device 10B may achieve better technical effects similar to that of the aforementioned embodiments.

In some other embodiments, FIG. 5B is a partially enlarged schematic diagram of a second wire according to still another embodiment of the disclosure. For the clarity of the drawings and the convenience of description, several elements are omitted in FIG. When a display device 10C has a design space due to pixel design arrangement adjustment or low resolution, a distance between the through hole TH1 and the through hole TH2 of the adjacent two paired sub-pixels SF (for example, the sub-pixel SP1′ and the sub-pixel SP2′) may be increased. In this way, the main portion 224 of the second wire 220 may extend into the through hole TH1 in the Y axis direction and be connected to the connection portion 222 on the side wall 162. The connection portion 222 then extends to the outer edge of the through hole TH1 in the Y axis direction to contact the main portion 224. In this way, the main portion 224 of the sub-pixel SP1′ and the main portion 224 of the sub-pixel SP2′ may extend to the auxiliary line L and may be disposed on the insulating layer 160 on two opposite sides of the auxiliary line L. Under the above configuration, the connection portions 222 of the adjacent second wires 220 are not easy to contact with each other, or the chance of electrical abnormality may be reduced. In addition, the connection structure 200 or the display device 10C may achieve better technical effects similar to that of the aforementioned embodiments.

FIG. 6 is a schematic cross-sectional view of FIG. 4 viewing along a section line B-B′. For the clarity of the drawings and the convenience of description, several elements are omitted in FIG. 6. The cross-sectional view of the display device 10B of FIG. 6 is substantially similar to the cross-sectional view of the display device 10 of FIG. 2, so that the same and similar components in the two embodiments are not repeated. In the embodiment, the insulating layer 120 is disposed on the substrate 110. The semiconductor layer SEMI is disposed on the insulating layer 120. The insulating layer 130 is disposed on the semiconductor layer SEMI. The gate G is disposed on the insulating layer 130. The insulating layer 140 is disposed on the gate G. The first wire 210 (for example, the drain D) is disposed on the insulating layer 140. The insulating layer 150 is disposed on the first wire 210. The insulating layer 160 is disposed on the insulating layer 150 and the first wire 210. The insulating layer 160 has the through hole TH1 and the through holes TH2 each surrounded by the side wall 162. The through hole TH1 and the through hole TH2 may be respectively disposed on the two opposite sides of the auxiliary line L. The connection portion 222 of the second wire 220 ends on the side wall 162 of the through hole TH1 or ends on the side wall 162 of the through hole TH2. For example, the connection portion 222 in the sub-pixel SP1′ on one side of the auxiliary line L is disposed on the side wall 162 surrounding the through hole TH1. The connection portion 222 in the sub-pixel SP2′ on the other side of the auxiliary line L is disposed on the side wall 162 surrounding the through hole TH2. The side wall 162 surrounding the through hole TH1 or the through hole TH2 has the high level surface HS and the low level surface LS. The side wall 162 surrounding the through hole TH1 or the through hole TH2 has the inclined surface SS. The inclined surface SS is located between the high level surface HS and the low level surface LS and may be connected to the high level surface HS and the low level surface LS.

In the embodiment, the insulating layer between the through hole TH1 and the through hole TH2 or overlapping the auxiliary line L may include an insulating layer 150′ and an insulating layer 160′, which may be used to define a height of the side wall 162 surrounding the through hole TH1 and the through hole TH2. To be specific, from the low level surface LS to the high level surface HS of the side wall 162 (i.e., the distance between the low level surface LS and the high level surface HS in the Z axis direction), a height H1′ of the side wall 162 surrounding the through hole TH1 or the through hole TH2 can be defined.

In some embodiments, heights of the insulating layer 160 far away from the auxiliary line L (or not between the through hole TH1 and the through hole TH2) and the insulating layer 160′ adjacent to the auxiliary line (or between the through hole TH1 and the through hole TH2) may be the same. The height of the insulating layer 160 and the insulating layer 160′ is, for example, defined as a vertical distance from the high level surface HS of the side wall 162 to the low level surface LS where the bottom surface of the side wall 162 contacts the insulating layer 150′. In some embodiments, the height of the insulating layer 160 and the height of the insulating layer 160′ may also be different. For example, the height of the insulating layer 160′ located between the through hole TH1 and the through hole TH2 may be reduced after the photolithography process. Therefore, the height of the insulating layer 160 may be greater than the height of the insulating layer 160′, but the disclosure is not limited thereto. In other embodiments, the height of the insulating layer 160 may also be smaller than the height of the insulating layer 160′.

In some embodiments, the outer edge 222′ of the connection portion 222 is set at a position not less than 10% of the height H1′ of the side wall 162, and the outer edge 222′ of the connection portion 222 is set at a position not greater than 90% of the height H1′ of the side wall 162. In other words, the height H2′ of the connection portion 222 on the side wall 162 may be greater than or equal to 10% of the height H1′, or less than or equal to 90% of the height H1′. In some other embodiments, the outer edge 222′ of the connection portion 222 is set at a position not less than 20% of the height H1′ of the side wall 162, and the outer edge 222′ of the connection portion 222 is set at a position not larger than 80% of the height H1′ of the side wall 162. In other words, the height H2′ of the connection portion 222 on the side wall 162 may be greater than or equal to 20% of the height H1′, or less than or equal to 80% of the height H1′, but the disclosure is not limited thereto. In this way, the outer edge 222′ of the connection portion 222 may stop on the inclined surface SS of the side wall 162. Since the connection portion 222 is disposed on the inclined surface SS, the connection portion 222 may be subjected to a better amount of exposure during the photolithography process, and the second wire 220 (for example, the pixel electrode PE) on the top surface of the insulating layer 160′ is also not easy to be overexposed. Under the above configuration, the size of the pixel electrode PE may be maintained to an appropriate size. In this way, the capacitance between the pixel electrode PE and the common electrode CE is less affected. The display device 10 may have better electrical quality or better display quality.

In summary, in the connection structure and the display device including the same of the embodiments of the disclosure, the connection portion of the second wire of the connection structure is disposed on the side wall of the through hole of the insulating layer. Therefore, the second wires of the adjacent sub-pixels may not easily contact each other, which reduces the chance of generation of electrical abnormalities. In addition, during the photolithography process, the connection portion is subjected to a better amount of exposure, and the second wire (for example, the pixel electrode) on the top surface of the insulating layer is also not easy to be overexposed. Under the aforementioned configuration, the size of the pixel electrode is maintained to an appropriate size. In this way, the capacitance between the pixel electrode and the common electrode is less affected. The display device including the connection structure may have better electrical quality or better display quality.

Finally, it should be noted that the above embodiments are only used to illustrate the technical solutions of the disclosure and are not used for limitation; although the disclosure has been described in detail with reference to the aforementioned embodiments, those of ordinary skills in the art should understand that the technical solutions recorded in the aforementioned embodiments may still be modified, or some or all of the technical features may be equivalently replaced; these modifications or replacements do not make the essence of the corresponding technical solutions deviate from the range of the technical solutions of the embodiments of the disclosure. The features between the embodiments may be mixed and matched arbitrarily as long as they do not violate or conflict with the spirit of the disclosure.

What is claimed is:

1. A connection structure, comprising:
a first wire;
a second wire;
a first insulating layer, disposed between the first wire and the second wire, and the first insulating layer having a through hole surrounded by a side wall, and a connection portion of the second wire being electrically connected to the first wire through the through hole; and
a second insulating layer, disposed on the second wire and filled in the through hole,
wherein the second insulating layer does not contact the first wire, and both of two outer edges of the connection portion are located within a contour of the through hole.

2. The connection structure as claimed in claim 1, wherein the first insulating layer is made of an organic material.

3. The connection structure as claimed in claim 1, wherein the connection portion of the second wire ends at a position not less than 10% and not greater than 90% of a height of the side wall.

4. The connection structure as claimed in claim 1, wherein the connection portion of the second wire ends at a position not less than 20% and not greater than 80% of a height of the side wall.

5. The connection structure as claimed in claim 1, wherein the side wall has a high level surface and a low level surface, the side wall surrounding the through hole has an inclined surface, and the inclined surface connects the high level surface and the low level surface.

6. The connection structure as claimed in claim 5, wherein there is a height difference between the high level surface and the low level surface, and the height difference is 1 μm to 6 μm.

7. The connection structure as claimed in claim 5, wherein there is a height difference between the high level surface and the low level surface, and the height difference is 3 μm to 5 μm.

8. The connection structure as claimed in claim 5, wherein the inclined surface comprises an arc-shaped curved surface.

9. The connection structure as claimed in claim 1, wherein the second wire further comprises a main portion, the main portion is disposed on the first insulating layer, and the main portion is connected to the connection portion.

10. The connection structure as claimed in claim 9, wherein the main portion is not overlapped with the through hole.

11. The connection structure as claimed in claim 1, wherein in a top view, a pattern of the through hole comprises a circle, a rectangle, a polygon, an ellipse, or an irregular shape.

12. An electronic device, comprising:
the connection structure as claimed in claim 1.

13. The electronic device as claimed in claim 12, further comprising:
a substrate;
a first signal line, disposed on the substrate; and
a second signal line, disposed on the substrate and arranged in intersection with the first signal line,
wherein the first wire is electrically connected to the second signal line.

14. The electronic device as claimed in claim 13, further comprising:
a thin film transistor, comprising:
a gate, electrically connected to the first signal line;
a semiconductor layer, partially overlapped with the gate; and
a source and a drain, electrically connected to the semiconductor layer, respectively.

15. The electronic device as claimed in claim 14, wherein the first wire is the drain, and the second wire is a pixel electrode.

16. The electronic device as claimed in claim 14, further comprising a plurality of sub-pixels, each of the plurality of sub-pixels comprising the second wire and the thin film transistor, and the second wire being electrically connected to the thin film transistor.

17. The electronic device as claimed in claim 16, wherein the two adjacent sub-pixels are respectively located on two sides of a reference line and arranged in a mirror manner.

18. The electronic device as claimed in claim 16, wherein the second wire of one of the two adjacent sub-pixels and the second wire of the other of the two adjacent sub-pixels are arranged correspondingly on two sides of a reference line.

19. The electronic device as claimed in claim 12, wherein the connection portion of the second wire is overlapped with the through hole.

20. The electronic device as claimed in claim 12, further comprising a common electrode, and the common electrode being disposed on the second insulating layer.
